(19) United States
(12) Patent Application Publication
(10) Pub. No.: US 2025/0320099 A1
(43) Pub. Date: Oct. 16, 2025

(54) Variable Current Load System and Control Method

(71) Applicant: Infintium Fuel Cell Systems, Inc., Greenville, SC (US)

(72) Inventor: Robert Morris Clippard, Greenville, SC (US)

(21) Appl. No.: 19/178,080

(22) Filed: Apr. 14, 2025

Related U.S. Application Data
(60) Provisional application No. 63/634,394, filed on Apr. 15, 2024.

(51) Int. Cl. B66F 9/24; B60L 3/12; B60L 50/40; B60L 50/75; B60L 58/33; B66F 9/075; H01M 8/04014; H01M 8/04537; H01M 8/04746; H01M 8/04858; H02J 1/10; H02J 1/14; H02M 1/00; H02M 3/157; H02M 3/158; H05K 1/18

(52) U.S. Cl. CPC B66F 9/24; B60L 3/12; B60L 50/40; B60L 50/75; B60L 58/33; B66F 9/07572; H01M 8/04014; H01M 8/04626; H01M 8/04753; H01M 8/04917; H01M 8/04947; H02J 1/102; H02J 1/14; H02M 1/0032; H02M 3/157; H02M 3/1582; B60L 2200/42; B60L 2210/12; B60L 2210/14; H01M 2250/20; H05K 1/181; H05K 2201/10015; H05K 2201/10053

(57) ABSTRACT

A system includes a plurality of power modules connected in parallel and a variable current load controller coupled to the plurality of power modules. The input terminals of the plurality of power modules are configured to be coupled to an output of a fuel cell stack, and the output terminals of the plurality of power modules are configured to supply power to a forklift. The plurality of power modules is further configured to provide electrical isolation between the fuel cell stack and the forklift. The variable current load controller is configured to regulate power distribution among the plurality of power modules.

### CROSS-REFERENCE TO RELATED APPLICATIONS

This patent application claims priority to U.S. Provisional Application No. 63/634,394, filed on Apr. 15, 2024 and entitled “Variable Current Load System and Control Method,” which is incorporated herein by reference as if reproduced in its entirety.

### TECHNICAL FIELD

The present invention relates to the field of fuel cell systems, and, in particular embodiments, to a variable current load system and control method thereof.

### BACKGROUND

Currently, lead-acid batteries are utilized to power for electric forklifts. In contrast to internal combustion engines, forklifts powered by lead-acid batteries operate quietly and offer a cleaner, more environmentally friendly alternative. However, lead-acid batteries are plagued by numerous issues in both production and use. During operation, as the capacity of the lead-acid battery diminishes, the performance of the forklift declines, resulting in reduced speed and inadequate lifting capacity, significantly impacting work efficiency. Moreover, lead-acid batteries require lengthy recharging periods after use. Additionally, the use of lead-acid batteries can lead to the generation of acid mist, a concern in certain logistic centers where the presence of detected lead is prohibited. Furthermore, the production of lead-acid batteries contributes to environmental pollution.

As technologies further advance, fuel cell systems have emerged as efficient and dependable power sources to replace lead-acid batteries in forklift applications. Compared to their lead-acid counterparts, fuel cell systems offer numerous advantages, including higher energy density, extended lifespan, rapid refueling/recharging capabilities, environmentally friendly operation, enhanced efficiency, scalability, and more.

Fuel cell systems are power supply systems designed to generate electricity through a chemical reaction between a fuel and an oxidizing agent. For instance, certain types of fuel cells utilize hydrogen as the fuel and oxygen from the air as the oxidizer, producing only water and heat as byproducts. These systems generate electricity with significantly lower emissions compared to conventional combustion-based technologies, presenting a clean, efficient, and adaptable solution for various power generation needs.

In a forklift fuel cell system, in order to seamlessly replace the existing lead-acid battery without necessitating modifications to the forklift itself, all components must be consolidated within a rectangular chamber. The forklift fuel cell system includes various elements such as a controller, an energy storage device, a dc/dc power converter, a contactor, a fuel cell system, a hydrogen filling valve, a hydrogen bottle, a hydrogen system, etc. To achieve a weight equivalent to that of the lead-acid battery, additional weights must be incorporated.

Operation of a hydrogen fuel cell requires a load. During the design and development of hydrogen fuel cell systems for industrial forklift applications, it has been proven beneficial to fuel cell stack life and system operation to be able to decouple the fuel cell stack from the highly dynamic load conditions of the vehicle being powered. It is desirable to have a reliable and efficient current load for these applications. The present disclosure addresses this need.

### SUMMARY

These and other problems are generally solved or circumvented, and technical advantages are generally achieved, by preferred embodiments of the present disclosure which provide a variable current load for fuel cell applications.

In accordance with an embodiment, a system comprises a plurality of power modules connected in parallel, and a variable current load controller coupled to the plurality of power modules. The input terminals of the plurality of power modules are configured to be coupled to an output of a fuel cell stack, and the output terminals of the plurality of power modules are configured to supply power to a forklift. The plurality of power modules is further configured to provide electrical isolation between the fuel cell stack and the forklift. The variable current load controller is configured to regulate power distribution among the plurality of power modules.

In accordance with another embodiment, a variable current load system comprises a plurality of power modules on a board in a package and a variable current load controller on the board and parallel to the plurality of power modules. The output terminals of the plurality of power modules are aligned with an output terminal of the package, and wherein the output terminal of the package is configured to supply power to a forklift. The input terminals of the plurality of power modules are aligned with an input terminal of the package, and wherein the input terminal of the package is configured to be connected to an output terminal of a fuel cell stack. The plurality of power modules is configured to emulate a battery providing power to the forklift. The variable current load controller is configured to regulate power distribution among the plurality of power modules.

In accordance with another embodiment, a method comprises providing power from a fuel cell stack to a variable current load system, the variable current load system comprising a plurality of power modules connected in parallel, and a variable current load controller coupled to the plurality of power modules, configuring the variable current load controller to regulate power distribution among the plurality of power modules, and delivering output power from the variable current load system to a forklift and an energy storage device.

Features described in the context of one embodiment may be used in combination with other embodiments. For example, each of the optional features described above in the context of the apparatus may be used in combination with the system. Each of the optional features described above in the context of the method may be used in combination with the system. Each of the optional features described above in the context of the apparatus may be used in combination with the method.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a perspective view of an example fuel cell power supply system in accordance with various embodiments of the present disclosure;

FIG. 2 is a schematic block diagram of the example fuel cell power supply system in FIG. 1 in accordance with various embodiments of the present disclosure;

FIG. 3 illustrates a block diagram of an example fuel cell system in accordance with various embodiments of the present disclosure;

FIG. 4 illustrates a schematic diagram of an example power module from the plurality of power modules within a current load system, in accordance with various embodiments of the present disclosure;

FIG. 5 illustrates a block diagram of an example current load system in accordance with various embodiments of the present disclosure;

FIG. 6 illustrates a top view of a layout of a power module in accordance with various embodiments of the present disclosure;

FIG. 7 illustrates a package configured to accommodate a variable current load system, which includes four power modules as shown in FIG. 6, in accordance with various embodiments of the present disclosure;

FIG. 8 is a flowchart of an example method for controlling a variable current load system in accordance with various embodiments of the present disclosure;

FIG. 9 is a flowchart of an example method for controlling a variable current load system in accordance with various embodiments of the present disclosure;

FIG. 10 is a flowchart of an example method for controlling a variable current load system in accordance with various embodiments of the present disclosure;

FIG. 11 is a flowchart of an example method for controlling a variable current load system in accordance with various embodiments of the present disclosure; and

FIG. 12 illustrates a flow chart of a method for controlling for controlling a variable current load system in accordance with various embodiments of the present disclosure.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure. Further, it should be understood that various changes, substitutions and alterations can be made herein without departing from the spirit and scope of this disclosure as defined by the appended claims.

Further, one or more features from one or more of the following described embodiments may be combined to create alternative embodiments not explicitly described, and features suitable for such combinations are understood within the scope of this disclosure. It is therefore intended that the appended claims encompass any such modifications or embodiments.

In addition, terms “first”, “second”, and so on, are only used to distinguish one feature (e.g., one entity or operation) from another feature (e.g., another entity or operation), and should not be interpreted as indicating or implying a relative importance, an order, or a quantity of indicated features. A feature limited with “first” or “second” may explicitly indicate or implicitly include one or more of the features.

The present disclosure will be described with respect to preferred embodiments in a specific context, namely a variable current load system and its control method for fuel cell applications. The disclosure may also be applied, however, to a variety of applications. Hereinafter, various embodiments will be explained in detail with reference to the accompanying drawings.

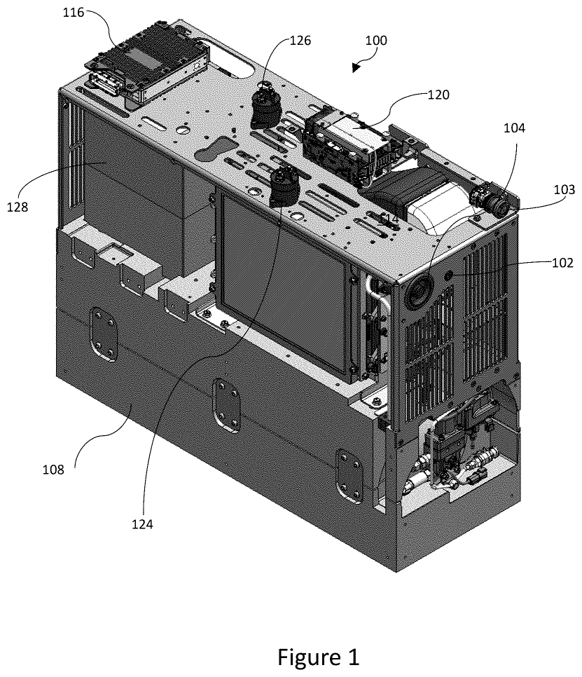

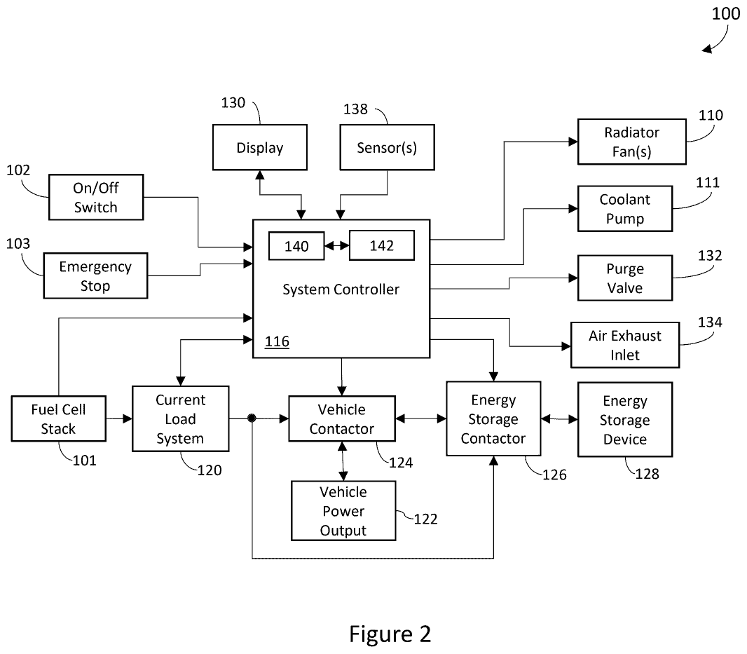

The following description is provided with reference to FIGS. 1 and 2. FIG. 1 illustrates a perspective view of an example fuel cell power supply system 100 in accordance with embodiments of the present disclosure. FIG. 2 is a schematic block diagram of the fuel cell power supply system 100 in FIG. 1, which shows an example implementation of the fuel cell power supply system. The terms of “fuel cell power supply system”, “fuel cell system” and “system” are used interchangeably in the present disclosure. In this example, the fuel cell power supply system 100 uses hydrogen as the fuel. However, hydrogen is merely used as an example for illustration purpose. Any other fuel applicable for fuel cell power systems may also be used.

The fuel cell power supply system 100 as shown in FIG. 1 may comprise a fuel cell stack 101, an on/off switch 102, an emergency stop switch 103, a fill port 104, a pressure regulator 106, a fuel storage tank 107, a system base frame 108, a system controller 116, a variable current load system 120, a vehicle power output 122, a vehicle contactor 124, an energy storage contactor 126, an energy storage device 128, and a purge valve 132. The fuel cell system 100 may further comprise a radiator fan 110, a coolant pump 111, an air compressor 115, a display 130, an air exhaust inlet 134, and one or more sensors 138. For clarity, some components are not illustrated in FIG. 1 or FIG. 2 but are described herein to provide a comprehensive understanding of the system's functionality. The terms of “variable current load system” and “current load system” are used interchangeably in the present disclosure.

Components of the fuel cell system 100 in this example are mainly arranged on or above the system base frame 108 in a system housing (not shown). The fuel cell stack 101 may be arranged close to a rear plate of the fuel cell system 100. As an example, the fuel cell stack 101 may be mounted on the rear plate. The rear plate may be part of the system housing. The fuel cell stack 101 may include one or more fuel cells, which may be combined in series into a fuel cell stack (stacked on top of each other) as typically used. A fuel cell is an electrochemical cell that converts chemical energy of a fuel (e.g., hydrogen) and an oxidizing agent (e.g., oxygen) into electricity. As well known, a fuel cell typically includes an anode, cathode, and an electrolyte membrane. In operation, hydrogen is passed through the anode, while oxygen is passed through the cathode. At the anode, a catalyst splits the hydrogen molecules into electrons and protons. The protons pass through the porous electrolyte membrane, while the electrons pass through a circuit, generating an electric current. At the cathode, the protons, electrons, and oxygen combine to produce water and heat. A typical fuel cell stack may include hundreds of fuel cells. The amount of power produced by a fuel cell may depend upon various factors, such as the fuel cell type, the fuel cell size, the temperature at which it operates, and the pressure of the gases supplied to the fuel cells, and so on.

The on/off switch 102 is used to turn on or off the fuel cell system 100. The emergency stop switch 103 is configured to stop operation of the fuel cell system 100 immediately in case of emergency, e.g., by cutting off the supply of the fuel.

The fuel (i.e., hydrogen) of the fuel cell system 100 is stored in the fuel tank 107. The fuel tank 107 may be arranged below the fuel cell stack 101. Hydrogen may be filled into the fuel tank 107 through the fill port 104. Fuel stored in the fuel tank 107 is maintained at a specific pressure level, which can be regulated using the pressure regulator 106 to ensure optimal operation of the fuel cell system.

A radiator assembly may include cooling components such as the radiator fan 110 for dissipating heat generated during the operation of the fuel cell stack 101 and the coolant pump 111 for circulating coolant throughout the system to transfer heat away from critical components. Hot/warm exhaust air from the fuel cell stack 101 may enter the air exhaust inlet 134 be cooled down through the radiator assembly, and be re-circulated back to the fuel cell stack 101. In some embodiments, the system may employ air exhaust fans as an alternative to radiator fans for thermal management. In such configurations, the system relies on air cooling, eliminating the need for a coolant pump and liquid-based cooling components. The air exhaust fans may be strategically positioned to enhance airflow across the fuel cell stack 101, dissipating heat generated during operation. These air exhaust fans may be controlled based on temperature readings from one or more sensors 138 to optimize cooling performance. The purge valve 132 may temporarily open during the purging process of the fuel cell stack 101 to discharge purge exhaust. The purge exhaust may primarily include water and non-reactive components, such as traces of unreacted hydrogen, and possible impurities entering the fuel.

The amount of air available for the electrochemical reaction at the fuel cell stack 101 affects the performance of the fuel cell system 100. Fuel cell performance improves as the pressure of the reactant gases increases. The air compressor 115 is used to push air into the fuel cell stack 101 such that the air is provided to the fuel cell stack 101 at a desired flow rate. As an example, the air compressor 115 may raise the pressure of the incoming air of the fuel cell stack 101 to about 2˜4 times the ambient atmospheric pressure of the fuel cell stack 101.

The fuel cell stack 101 is coupled to a current load system 120. Fuel cells generate electricity in the form of direct current (DC). The electric power generated by the fuel cell stack 101 may be converted to different levels of DC power to match various load requirements by the current load system 120, e.g., to low DC power and high DC power by the current load system 120, respectively. As an example, the current load system 120 may be configured to convert a DC voltage output by the fuel cell stack 101 to desired voltage(s).

The system controller 116 is configured to manage and control operation of the fuel cell system 100. The system controller 116 may include one or more processors 140, such as microprocessors or microcontrollers, which are appropriately configured to carry out fuel cell system operations. The system controller 116 may further include a computer-readable storage device 142 storing computer-readable instructions, which may be executed by the one or more processors 140 of the system controller 116 for carrying out the fuel cell system operations. The computer-readable storage device 142 may include any non-transitory mechanism for storing information in a form readable by a machine (e.g., a computer, a processor). For example, a computer-readable storage device may include read-only memory (ROM), random-access memory (RAM), magnetic disk storage media, optical storage media, flash-memory devices, solid state storage media, and other storage devices and media.

The system controller 116 may be a controller with an integrated design, which may be a scattered fuel cell controller, a whole vehicle controller, or a battery energy management system. The system controller 116 may incorporate various functional units, such as an energy management unit, a fuel cell control unit, an energy storage device monitoring unit, a hydrogen safety monitoring unit, a system failure monitoring unit and/or a startup control unit.

As shown in FIG. 2, the system controller 116 may be connected to various components of the fuel cell system 100, such as the fuel cell stack 101, the on/off switch 102, the emergency stop 103, radiator fan(s) 110, the coolant pump 111, the current load system 120, the vehicle power output 122 through the vehicle contactor 124, the energy storage 128 through the energy storage contactor 126, the display 130, the purge valve 132, the air exhaust inlet 134, and one or more sensors 138.

As an example, when the on/off switch 102 is switched off, the system controller 116 may receive a signal indicating the switching off of the on/off switch 102, and control to stop operations of the fuel cell system 100, e.g., cutting off the fuel supply to the fuel cell stack 101, turning off the radiator fan(s) 110, and so on. As another example, the system controller 116 may control supplying power to external power receiver(s) and storing energy in the energy storage device 128. As yet another example, the system controller 116 may control to close and open the purge value 132 to discharge fuel exhaust.

The system controller 116 may be connected to the display 130, through which users/operators may interact with the fuel cell system 100. For example, a user may enter instructions through the display 130 and/or set parameter(s) for operations of the fuel cell system 100. A user may monitor operation status or parameters/information displayed on the display 130. In some embodiments, the display 130 may be integrated with the system controller 116.

The system controller 116 may be connected to one or more sensors 138. The sensor(s) 138 may include various devices for detecting/sensing/measuring parameters of the fuel cell system 100, such as thermometer(s), timer(s), gas density sensor(s)/meter(s), moisture meter(s), and so on. The sensor(s) 138 may be positioned at various locations depending on their purposes.

The energy storage contactor 126 and the vehicle contactor 124 are electrically controlled switches that can be turned on or off to regulate power flow. In some embodiments, the vehicle contactor 124 and the energy storage contactor 126 may be normal open type high-current contactors. The energy storage contactor 126 and the vehicle contactor 124 are mounted on an exterior surface of the system and extend above the exterior surface. The vehicle contactor 124 is connected to output terminals of the system, directing power to a load, such as a forklift. The energy storage contactor 126 is connected to the energy storage device 128, which stores energy for supplemental power. The energy storage contactor 126 and the vehicle contactor 124 can be controlled by the system controller 116, or other power management system, ensuring they are activated only when needed. The energy storage contactor 126 and the vehicle contactor 124 can be electrically connected in various suitable ways, depending on system design requirements, to enable stored energy to flow efficiently to the load when required.

The current load system 120 is connected to the vehicle power output 122 through the vehicle contactor 124. The fuel cell system 100 supplies electric energy generated by the fuel cell stack 101 to external devices/apparatus (referred to as external power receivers thereafter) through the vehicle power output 122. The current load system 120 may also be connected to the energy storage device 128 through the energy storage contactor 126. The electric energy generated by the fuel cell stack 101 may be stored in the energy storage device 128, e.g., a battery. When both the energy storage contactor 126 and the vehicle contactor 124 are activated, energy stored in the energy storage device 128 is supplied to the vehicle power output 122 through the energy storage contactor 126 and the vehicle contactor 124, supplying power to the load. This allows stored energy to supplement power from the fuel cell stack 101, ensuring stable power delivery during high-demand periods.

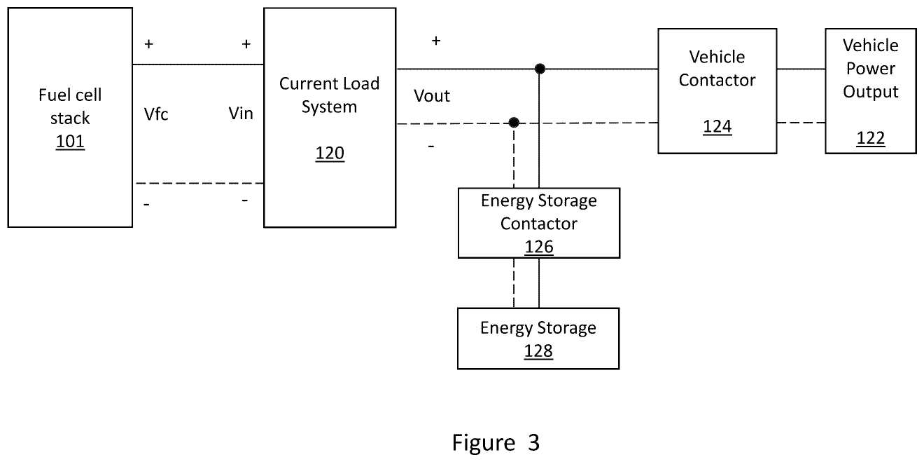

FIG. 3 illustrates a block diagram of an example fuel cell system in accordance with various embodiments of the present disclosure. As shown in FIG. 3, the fuel cell stack 101 generates an output voltage (Vfc) at its output terminals, which is supplied to input terminals (Vin) of the current load system 120. More particularly, a positive output terminal of the fuel cell stack 101 is connected to a positive input terminal of the current load system 120, while a negative output terminal of the fuel cell stack 101 is connected to a negative input terminal of the current load system 120. The outputs of the current load system 120 (Vout) are distributed to the vehicle power output 122 through the vehicle contactor 124 and to the energy storage device 128 through the energy storage contactor 126. More particularly, a positive output terminal of the current load system 120 is connected to a positive input terminal of the vehicle contactor 124, while a negative output terminal of the current load system 120 is connected to a negative input terminal of the vehicle contactor 124. A positive output terminal of the vehicle contactor 124 is connected to a positive input terminal of the vehicle power output 122, while a negative output terminal of the vehicle contactor 124 is connected to a negative input terminal of the vehicle power output 122. Similarly, the positive output terminal of the current load system 120 is connected to a positive input terminal of the energy storage contactor 126, while the negative output terminal of the current load system 120 is connected to a negative input terminal of the energy storage contactor 126. A positive output terminal of the energy storage contactor 126 is connected to a positive input terminal of the energy storage device 128, while a negative output terminal of energy storage contactor 126 is connected to a negative input terminal of the energy storage device 128. In some embodiments, the energy storage device 128 may comprise a plurality of battery cells that store excess energy from the fuel cell stack 101 and may supplement power to external power receivers as needed.

Both the vehicle power outlet 122 and the energy storage device 128 share the same output voltage (Vout) when their respective contactors are closed. More specifically, when the vehicle contactor 124 is closed, the vehicle power output 122 is connected to Vout, allowing an external power receiver, such as a forklift, to be powered by the fuel cell stack 101 through the current load system 120. When the energy storage contactor 126 is closed, the energy storage 128 is connected to Vout, allowing it to store excess energy from the fuel cell stack 101. If both the vehicle contactor 124 and the energy storage contactor 126 are closed simultaneously, the vehicle power output 122 and the energy storage 128 are connected in parallel to Vout. If Vout is sufficient, the fuel cell stack 101 serves as the primary power source for the vehicle power output 122, and the energy storage 128 can be charged by the fuel cell stack 101. If the fuel cell stack 101 is unable to supply sufficient power, or its output voltage drops below the required level, the energy storage 128 discharges to stabilize Vout and maintain system operation. In extreme cases where the fuel cell stack 101 is offline or unable to generate power, the energy storage 128 may function as the primary power source.

Hydrogen fuel cells require a load to operate effectively. The current load system 120 disclosed herein serves as a controllable current load, providing the necessary load for the fuel cell stack 101 while isolating the fuel cell stack 101 from the rest of the system. This isolation allows for a voltage differential between the fuel cell stack voltage at any given current and the system being protected. This controllable current load provides multiple functionalities. First, it provides a current load to control fuel cell operating point. Second, it provides over-voltage protections to prevent damage to load components. Third, it provides voltage conversion to allow the fuel cell stack to power multiple voltage systems. Fourth, it provides over-current protections to prevent overloading of the fuel cell stack. Fifth, it provides reverse current protections to prevent the fuel cell from being driven as a load, thereby mitigating the risk of irreversible damage.

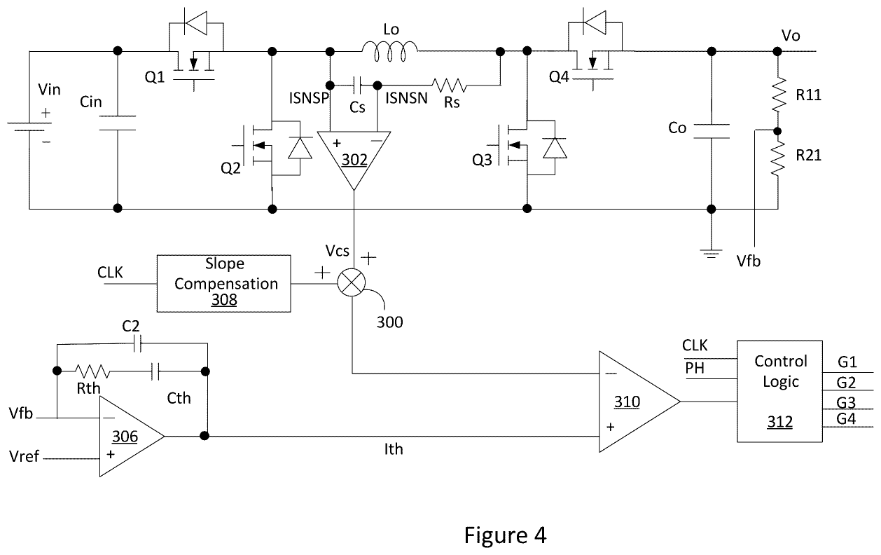

FIG. 4 illustrates a schematic diagram of an example power module from a plurality of power modules within a current load system 120, in accordance with various embodiments of the present disclosure. The current load system 120 comprises a plurality of power modules connected in parallel, and a variable current load controller coupled to the plurality of power modules. The terms of “variable current load controller” and “current load controller” are used interchangeably in the present disclosure. In some embodiments, the number of the power modules is in a range from 1 to 4 power modules depending on the required current availability.

Each power module in the variable current load system 120 may be implemented as a four-switch buck-boost converter. As illustrated in FIG. 4, each buck-boost converter comprises a first high-side switch Q1, a first low-side switch Q2, a second low-side switch Q3, a second high-side switch Q4, and an inductor Lo. Each power module further comprises a control circuit. The control circuit may comprise a current-sense amplifier 302, an error amplifier 306, a slope compensation block 308, a comparator 310, a control logic unit 312, and a feedback circuit. In some embodiments, the feedback circuit comprises a voltage divider formed by resistors R11 and R21, and a current sensing network comprising a sense resister Rs and a sense capacitor Cs. It should be noted that other current-sensing methods can also be implemented, depending on system requirements and design constraints. Together, these components form a power module capable of performing both power conversion and control functions within the variable current load system 120.

The first high-side switch Q1 and the first low-side switch Q2 are connected in series between an input voltage bus Vin and ground. The input voltage Vin is connected to the drain of Q1, while the source of Q1 is connected to the drain of Q2, with the source of Q2 grounded. The second high-side switch Q4 and the second low-side switch Q3 are connected in series between an output of the power module and ground. The drain of Q4 is connected to the drain of Q3, while the source of Q3 is grounded. The inductor Lo is connected between a first common node of Q1 and Q2, and a second common node of Q4 and Q3 as shown in FIG. 4. An input capacitor Cin is connected between Vin and ground, while an output capacitor Co is connected between an output voltage Vo and ground to stabilize voltage fluctuations. A sense resister Rs and a sense capacitor Cs are connected in series between the two terminals of the inductor Lo, creating a filtered voltage proportional to the inductor current. The common node between Cs and Lo is labeled as ISNSP, while the common node between Cs and Rs is labeled as ISNSN. The current-sense amplifier 302 receives ISNSP at its non-inverting input and ISNSN at its inverting input, thereby measures the voltage difference across Cs. The current-sense amplifier 302 amplifies this difference to produce a current sense voltage (Vcs). The slope compensation block 308 receives a clock signal (CLK) input to produce a slope compensation ramp signal. Vcs is then combined at node 300 with the slope compensation ramp signal to produce a compensated current sense signal. The compensated current sense signal is then fed into the inverting input of comparator 310.

The feedback circuit monitors the output voltage Vo to regulate the power module's operation. The voltage divider, consisting of R11 and R21, is connected Vo and ground, generating a feedback voltage Vfb. The feedback voltage Vfb is proportional to the output voltage (Vo) of the power module. The error amplifier 306 receives a reference voltage Vref at its non-inverting input terminal and the feedback voltage Vfb at its inverting input terminal. To ensure stability and optimize transient response, a compensation network is employed. Capacitor C2 is connected between the output of the error amplifier 306 and Vfb, while resistor Rth and capacitor Cth are connected in series between the output of the error amplifier 306 and the inverting input terminal of the error amplifier 306. The error amplifier 306 compares Vfb with Vref and generate an output signal denoted as Ith. The Ith signal is then fed into the non-inverting input of the comparator 310. Comparator 310 compares the Ith signal with the compensated current sense signal at its inverting input, generating a control signal that is sent to the control logic unit 312. The control logic unit 312 receives the control signal from the comparator 310, along with the CLK signal and a phase select signal PH. The control logic unit 312 then generates PWM switching signals G1, G2, G3, and G4 to regulate the operation of Q1, Q2, Q3, and Q4 respectively, ensuring that the power module operates in the required mode. The duty cycle of these PWM signals determines the switching behavior of Q1, Q2, Q3, and Q4, thereby controlling the power conversion process and regulating the output voltage accordingly. When a plurality of power modules are connected in parallel, CLK synchronizes the switching frequency across all power modules, while PH sets the phase offset for each module, allowing their PWM signals to be interleaved and reducing overall ripple.

The buck-boost converter in each power module may be divided into two portions, namely a buck converter portion and a boost converter portion. The buck converter portion may comprise the first high-side switch Q1 and the first low-side switch Q2. The buck converter portion and the inductor Lo may function as a step-down converter when the second high-side switch Q4 is always on and the second low-side switch Q3 is always off. Under such a configuration, the buck-boost converter operates in a buck mode.

The boost converter portion of the buck-boost converter may comprise the second high-side switch Q4 and second low-side switch Q3. The boost converter portion and the inductor Lo may function as a step-up converter when the first high-side switch Q1 is always on and the first low-side switch Q2 is always off. Under such a configuration, the buck-boost converter operates in a boost mode. Furthermore, the buck-boost converter operates in a pass-through mode when the high-side switches Q1 and Q4 are always on, and the low-side switches Q2 and Q3 are always off. In operation, based upon different application needs, the buck-boost converter may be configured to operate in three different operating modes, namely the buck mode, the boost mode and the pass-through mode.

In buck mode, Q1 and Q2 operate in a switching manner, while Q4 remains continuously on and Q3 remains off, allowing step-down conversion. In boost mode, Q3 and Q4 switch actively, while Q1 remains on and Q2 remains off, facilitating step-up conversion. In pass-through mode, both Q1 and Q4 are always on, while Q2 and Q3 remain off, directly passing the input voltage to the output.

The switches (e.g., the first high-side switch Q1) shown in FIG. 4 may be implemented as n-type metal oxide semiconductor (NMOS) transistors. Alternatively, the switches may be implemented as other suitable controllable devices such as metal oxide semiconductor field effect transistor (MOSFET) devices, bipolar junction transistor (BJT) devices, super junction transistor (SJT) devices, insulated gate bipolar transistor (IGBT) devices, gallium nitride (GaN) based power devices and/or the like.

It should further be noted that while FIG. 4 illustrates four switches Q1, Q2, Q3, and Q4, various embodiments of the present disclosure may include other variations, modifications and alternatives. For example, the first low-side switch Q2 may be replaced by a freewheeling diode and/or the like. The second high-side switch Q4 may be replaced by a rectifier diode and/or the like.

In operation, the resistor Rth may be adjusted to modify the Ith output of the error amplifier 306, thereby influencing the power module's regulation behavior. This change in Ith directly affects the duty cycle of the PWM output—by raising or lowering Ith, the on-time of the switching signals adjusts accordingly, thereby controlling the power module's overall behavior and output regulation. In some embodiments, the resistor Rth may be adjusted via a Serial Peripheral Interface (SPI) varistor by the variable current load controller to regulate an output current of the power module to maintain balanced current distribution among the plurality of power modules.

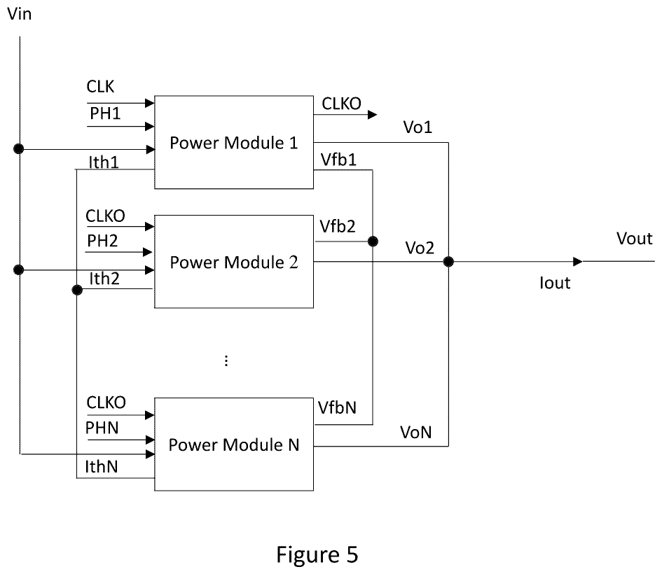

FIG. 5 illustrates a block diagram of an example current load system in accordance with various embodiments of the present disclosure. As shown in FIG. 5, the current load system 120 comprises a plurality of power modules connected in parallel, and a current load controller (not shown) coupled to the plurality of power modules. In some embodiments, each power module of the plurality of power modules is implemented as a buck-boost power converter. The current load system 120 is configured to regulate the voltage and control the current fed into the external power receivers.

As illustrated in FIG. 5, the input voltage Vin is distributed to each power module (Power Module 1, Power Module 2, . . . , Power Module N). Vin is derived from an output voltage (Vfc) of the fuel cell stack, and the input terminals of the plurality of power modules are configured to be connected to Vin. A clock signal is provided to each power module so their switching cycles remain synchronized. In some embodiments, one power module (e.g. the first power module) may function as the master phase, generating an output clock signal (CLKO). The other power modules may function as slave phases and receive the clock signal CLKO and synchronize their switching cycles with the master phase. In some other embodiments, each power module may receive an external clock signal to synchronize its operation. Each power module may also receive a phase select signal (PH1, PH2, . . . , PHN) to ensure interleaved operation. In some embodiments, the Ith nodes of all power modules (Ith1, Ith2, . . . , IthN) are connected together, forming a common current control reference that ensures uniform current sharing among the power modules. In some embodiments, the Vfb nodes of all power modules are connected together, allowing for coordinated voltage regulation and ensuring that all power modules contribute to maintaining a stable output voltage (Vout). The individual output voltages (Vo1, Vo2, . . . , VoN) from each power module are combined at a common node, forming the final Vout. The total output current (Iout) is the sum of the currents supplied by each power module. The output terminals of the plurality of power modules are configured to supply power to a load, such as a forklift. The output terminals of the plurality of power modules are further configured to be connected to input terminals of an energy storage device via an energy storage contactor. The energy storage device may comprise a plurality of battery cells configured to store energy from the fuel cell stack and supply power to the forklift when needed.

The current load system 120 is managed via a controller area network (CAN) interface. In some embodiments, the current load system 120 receives current load requests via the CAN interface from the system controller 116. In some embodiments, this system allows a supervisory controller to request a specific current load for the fuel cell stack. The supervisory controller may be integrated into the system controller 116 (e.g., as part of the Energy Management Unit) or it may be implemented as a separate controller. The supervisory controller or the system controller 116 monitors system parameters—such as load demand, fuel cell performance, and environmental conditions—and then sends current load requests via the CAN interface to the current load controller within the current load system 120.

The current load controller of the current load system 120 is configured to handle all CAN communications, process performance sensor information, and coordinate power module operations. The current load controller receives current load requests over CAN, interprets them, and transmits operational commands to the power modules via SPI (Serial Peripheral Interface), while ensuring that temperature limits are not exceeded. Additionally, the current load controller may also aggregate system performance data, conduct diagnostics, and oversee ramp-up and unload timing. The current load controller may also manage informational sensors, collect and relay performance data over CAN for system monitoring and control. The performance data may be sent to the system controller 116 or the supervisory controller, if present, for analyzing system performance. Each power module independently manages synchronization, switching, output overvoltage protection, and reverse current protection, ensuring stable and safe operation.

Upon receiving a current load request, the current load controller configures the plurality of power modules and draws the specified current from the fuel cell stack 101 through the input terminals of the current load system 120, thereby regulating the fuel cell stack's operating point and functioning as a controllable load. The current load system 120 will continue performing its function as long as it stays within temperature, output voltage, and reverse current limits. If any of these limits are exceeded, the current load system 120 will either reduce its operation or shut down entirely to protect both the fuel cell stack and the overall system.

In some embodiments, the variable current load controller is configured to evenly distribute the required current among the plurality of power modules, ensuring balanced load sharing and efficient operation. This process is executed by utilizing an SPI-controlled varistor to modulate the feedback resistor of each power module (e.g. Rth of each power module), enabling adjustment of the desired output current. In some embodiments, the current load system 120 may comprise four power modules connected in parallel, with each power module sharing the same input and output voltage bus. For example, if the system requires a total current (Iout) of 100A and there are four power modules, each power module would ideally supply 25A. However, due to component tolerances and other operational factors, the actual output from each module may deviate from this ideal, resulting in an uneven current distribution. To address this, the system continuously monitors the current from each module and adjusts an internal feedback or resistor parameter (e.g. Rth of each power module) to ensure that each module supplies an equal share of the total current.

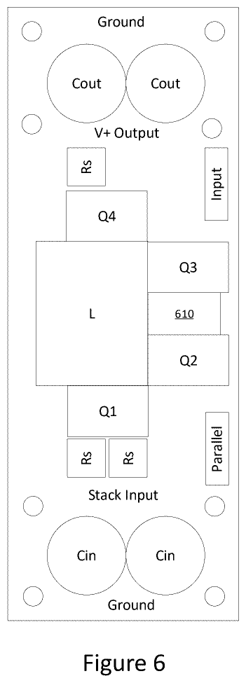

FIG. 6 illustrates a top view of a layout of a power module in accordance with various embodiments of the present disclosure. Each power module of the plurality of power modules in the variable current load system is configured as a buck-boost converter (e.g., the buck-boost converter shown in FIG. 3). The plurality of power modules is configured to provide electrical isolation between the fuel cell and the forklift. In some embodiments, each power module of the plurality of power modules is placed on a printed circuit board. The power module comprises a plurality of input capacitors Cin, a first power switch Q1, a second power switch Q2, a third power switch Q3, a fourth power switch Q4, a magnetic device L, a plurality of output capacitors Cout, a controller 610, a plurality of passive components and a plurality of auxiliary integrated circuits. In some embodiments, the controller 610 may be implemented as an integrated circuit (IC) on PCB, which may comprise a control circuit for managing the buck-boost operation, voltage and current sensing circuits, a communication interface, and protection mechanisms. The communication interface may include Controller Area Network (CAN) and/or Serial Peripheral Interface (SPI). The protection mechanisms may include overvoltage protection, overcurrent protection, and thermal shutdown, among others.

As shown in FIG. 6, the plurality of input capacitors Cin is placed between a ground node and an input terminal of the power module (stack input). The plurality of output capacitors Cout is placed between a ground node and an output terminal of the power module (V+ output). The output terminal of the power module delivers regulated power to a load after processing the stack input through the buck-boost converter. The magnetic device L is centrally positioned on the board and has a first side, a second side, a third side, and a fourth side. The first power switch Q1 is placed between the plurality of input capacitors Cin and the magnetic device L. It is placed adjacent to the magnetic device L, with a first side of Q1 aligned with the first side of the magnetic device L and a second side of Q1 aligned with the second side of the magnetic device L. The second power switch Q2 is placed adjacent both to the magnetic device L and the controller 610, with a first side of Q2 aligned with the second side of the magnetic device L. The third power switch Q3 is placed adjacent to both the magnetic device L and the controller 610, arranged in parallel with Q2, with a first side of the Q3 aligned with the second side of the magnetic device L. The controller 610 is placed between the second power switch Q2 and the third power switch Q3, with a first side of the controller 610 aligned with the second side of the magnetic device L. The fourth power switch Q4 is placed between the plurality of output capacitors Cout and the magnetic device L, adjacent to the magnetic device L, with a first side of Q4 aligned with the third side of the magnetic device L and a second side of Q4 aligned with the second side of the magnetic device L. As shown in FIG. 6, the plurality of input capacitors Cin may comprise two input capacitors connected in parallel. The plurality of output capacitors Cout may comprise two output capacitors connected in parallel. As a result of the compact design, the layout area is minimized, enhancing power density, thermal dissipation, and efficiency.

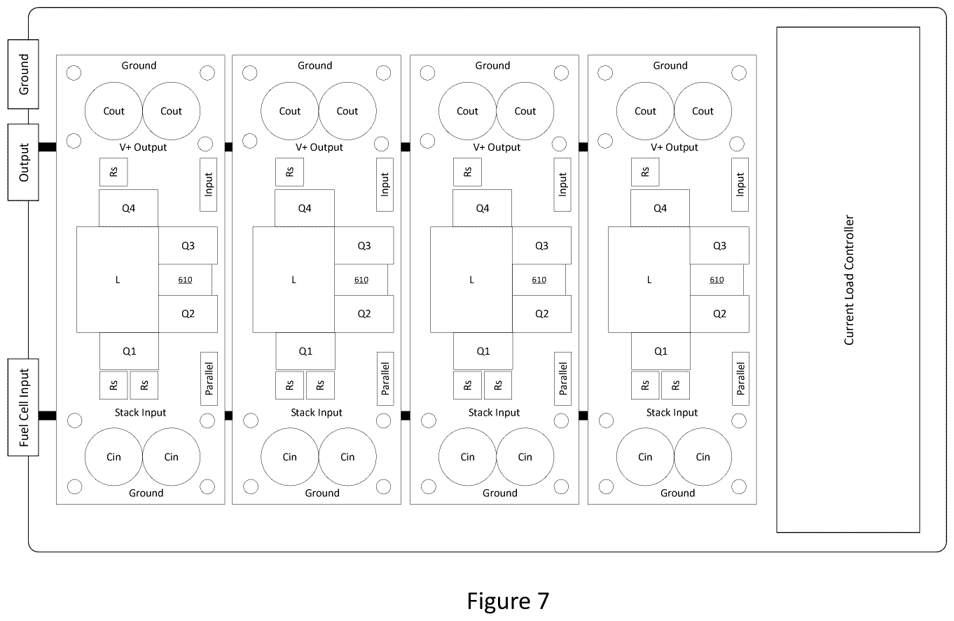

FIG. 7 illustrates a package configured to accommodate a variable current load system, which includes a plurality of power modules as shown in FIG. 6, in accordance with various embodiments of the present disclosure. The package provides physical protection to the plurality of power modules. The package shields the plurality of power modules from environmental factors like moisture, dust, mechanical stress and the like. This protection helps ensure the reliability and longevity of the plurality of power modules. Furthermore, the plurality of power modules generate heat during operation. The package may include various features such as heat sinks or thermal pads to dissipate the heat efficiently.

As shown in FIG. 7, the variable current load system comprises four power modules, which are placed in parallel on a board in a package. It should be noted that the number of the power modules is not limited to four and may be any number depending on system requirements. The variable current load system further comprises a variable current load controller positioned on the board and coupled to the power modules. The variable current load controller is configured to regulate power distribution among the power modules. The variable current load controller is placed in parallel to the plurality of power modules.

As shown in FIG. 7, the input terminals of the four power modules are aligned with the fuel cell input terminal of the package. The fuel cell input terminal is configured to be connected to the output terminal of a fuel cell stack. The stack input of the first power module (PM1) is directly connected to the fuel cell input terminal on the board. The parallel terminal of PM1 is internally connected to its stack input. Each subsequent power module (e.g., PM2, PM3, and PM4) receives input power via the parallel terminal from the previous module, ensuring all power modules receive the same fuel cell input voltage.

As shown in FIG. 7, the output terminals of the four power modules are aligned with an output terminal of the package. The output terminal is configured to supply power to a load, such as a forklift. The V+ output of the PM4 is connected to the input terminal of the PM3. This input terminal is internally connected to the V+ output of PM3, enabling a connection of output voltages across all power modules. The combined V+ output is routed to the package's output terminal. The ground terminals of all power modules may be connected together. In operation, the four power modules are configured to emulate a battery providing power to the load.

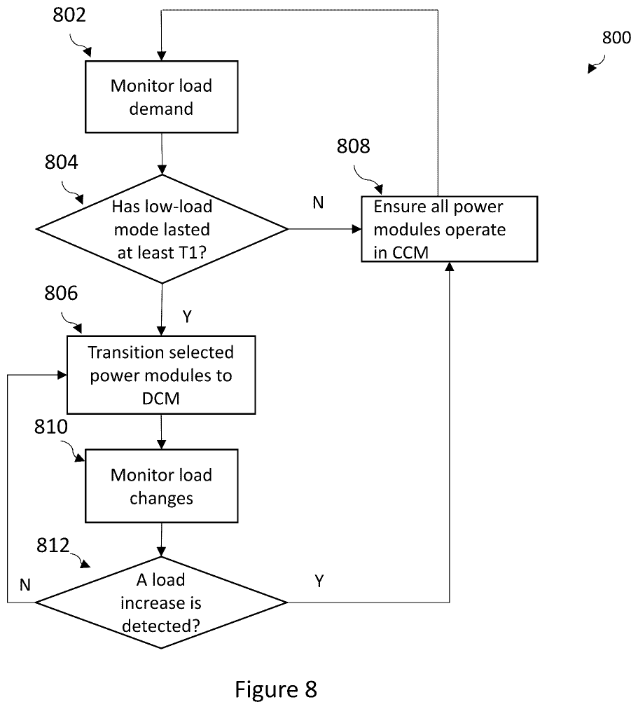

The detailed descriptions of FIGS. 8-12 will be provided below. It should be noted that the flowcharts shown in FIGS. 8-12 are merely examples and should not unduly limit the scope of the claims. One of ordinary skill in the art would recognize many variations, alternatives, and modifications. For example, various steps illustrated in FIGS. 8-12 may be added, removed, replaced, rearranged, or repeated.

Each power module phase has switching losses, conduction losses, and driver losses, regardless of the load. When the load is light, these fixed losses become a larger percentage of the total power, reducing efficiency. The current load controller may dynamically adjust the operation of the power modules based on load conditions in accordance with various embodiments of the present disclosure.

The power demand of a forklift can vary significantly between standby, movement, and lifting loads. During low-load conditions (e.g., light lifting), the current load controller may transition one or more power modules from Continuous Conduction Mode (CCM) into Discontinuous Conduction Mode (DCM), reducing switching losses while keeping them available for rapid load response. If the load decreases further (e.g., standby), the current load controller may put one or more power modules into sleep mode or shut them down completely, ensuring that only the necessary number of active power modules remain operational. In some embodiments, under low-load conditions, one power module may remain in CCM, while the other power modules operate in DCM, ensuring that the system maintains low power consumption while remaining ready to respond instantly when a sudden increase in power is required. In some other embodiments, the system may transition all power modules to DCM to minimize switching losses and improve efficiency. When load demand suddenly rises (e.g., the forklift lifts a heavy load), the current load controller reactivate sleeping power modules or transition those in DCM mode back into CCM to efficiently handle the increased load. This rapid response ensures sufficient current capacity when needed while minimizing energy losses at low load demand and quickly adapting to increased load demand.

FIG. 8 is a flowchart of an example method 800 for controlling a variable current load system in accordance with various embodiments of the present disclosure. The method 800 provides example operations performed at a fuel cell system, particularly in forklift applications. The fuel cell system 100 may utilize the system controller 116 in conjunction with the current load controller within the variable current load system 120 to regulate power distribution and optimize performance, as described with respect to FIGS. 1-7.

At step 802, the method begins by monitoring load demand. At step 804, based on the load demand, the system determines whether the system has been operating in a low-load mode for at least a predefined duration T1. The low-load mode may be defined based on one or more conditions, such as the output voltage of the system, the average inductor current dropping below a predefined threshold, or the duty cycle decreasing beyond a set limit. If the system remains in the low-load mode for at least T1, the current load controller within the current load system 120 selectively enables one or more power modules to enter DCM (step 806). In some embodiments, one power module may remain in CCM mode, while other power modules operate in DCM to improve efficiency. For a system with N power modules, the current load controller may dynamically adjust power delivery by enabling anywhere from 1 to N power modules to operate in DCM, adapting to real-time system demand while maintaining efficiency and responsiveness. Conversely, if the system does not satisfy the low-load condition at step 804—either due to a detected load increase at step 802, which results in a reset of the low-load duration, or because low-load mode duration has not yet reached the predefined duration T1—the system ensures all power modules operate in CCM mode (step 808), ensuring full power delivery with optimal current balancing. The system returns back to step 802 to keep monitoring load demand.

Once in DCM, the system continuously monitors load changes (step 810). At step 812, if a load increase is detected (e.g., when one or more conditions used to assess load demand exceed a predefined threshold), the system determines that the low-load mode is ended and transitions all power modules back to CCM mode (step 808). If no load increase is detected in step 812, the system remain in DCM mode (step 806) and keep monitoring load changes (step 810). In some embodiments, if further decreases in load demand are detected in step 810 while selected power modules are already operating in DCM mode, the system may transition additional power modules into DCM, further optimizing efficiency dynamically. The system may perform these adjustments in a loop at predefined time intervals, allowing the system to transition between DCM and CCM while avoiding excessive switching and instability.

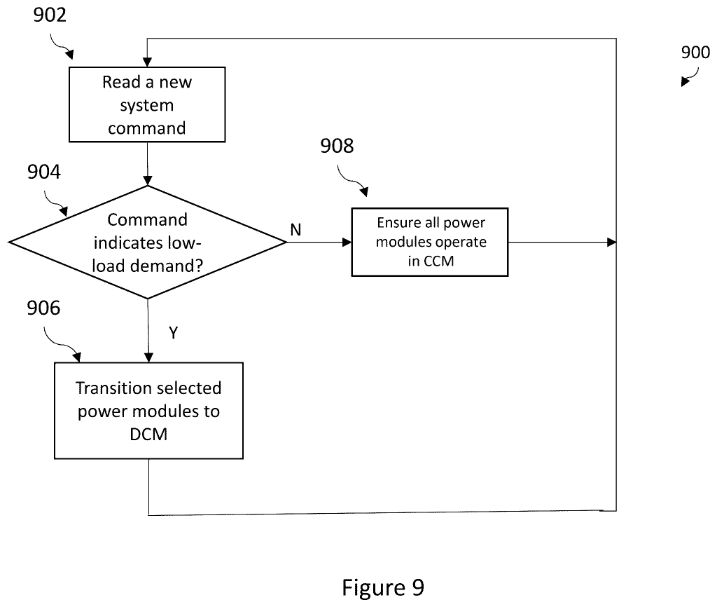

FIG. 9 is a flowchart of an example method 900 for controlling a variable current load system in accordance with various embodiments of the present disclosure. The method 900 provides example operations performed at a fuel cell system, particularly in forklift applications, where the fuel cell system 100 utilizes the system controller 116 in conjunction with the current load controller within the variable current load system 120, as described with respect to FIGS. 1-7.

The forklift vehicles operate under well-defined control signals, so the system may determine power requirements based on system commands. The system commands provide information on load demand, determining whether it is high or low based on factors such as acceleration, lifting operations, or other functional requirements.

At step 902, the method begins by reading a new system command, which may be processed either continuously or upon receiving an event trigger. At step 904, the system evaluates whether the system command indicates a low-load demand. If the system command does not indicate a low-load demand (e.g., during heavy lifting operations), the system enables all power modules to operate in CCM (step 908), ensuring full power delivery with optimal current balancing. However, if the system command indicates a low-load demand (e.g., standby or light lifting), the system transitions selected power modules to DCM (step 906) to improve efficiency. In some implementations, one power module may remain in CCM mode, while the remaining power modules operate in DCM. In some embodiments, if further decreases in load demand are detected in step 904 while selected power modules are already operating in DCM mode, the system may transition additional power modules into DCM, further optimizing efficiency dynamically. For a system with N power modules, the system can dynamically adjust power delivery by enabling anywhere from 1 to N power modules to operate in DCM, adapting to real-time system demand while maintaining efficiency and responsiveness. The system loops back to step 902 after step 906 to continue monitoring system commands. The system may perform these adjustments in a loop at predefined time intervals, allowing the power modules to transition between DCM and CCM while avoiding excessive switching and instability.

If the forklift remains in the low-load mode for an extended period, certain power modules can enter a “sleep” mode, shutting down non-essential circuitry to further conserve energy in accordance with various embodiments of the present disclosure. When the system senses a sudden increase in load demand—such as when lifting a heavy load—the system rapidly activates any sleeping modules and transitions them to DCM or CCM. This quick response guarantees that sufficient current capacity is available exactly when it's required, balancing low-load efficiency with robust high-load performance.

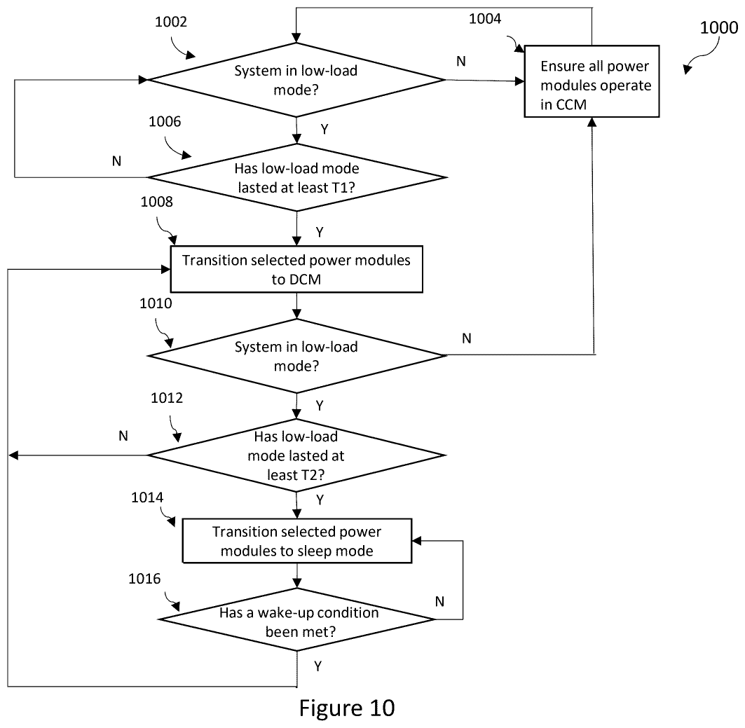

FIG. 10 is a flowchart of an example method 1000 for controlling a variable current load system in accordance with various embodiments of the present disclosure. The method 1000 provides example operations performed at a fuel cell system, particularly in forklift applications, where the fuel cell system 100 utilizes the system controller 116 in conjunction with the current load controller within the variable current load system 120, as described with respect to FIGS. 1-7.

The system begins by monitoring a load demand and determining whether it is in a low-load mode (step 1002). The determination of low-load mode is based on one or more conditions, such as the output voltage of the system, the average inductor current dropping below a predefined threshold, or the duty cycle decreasing beyond a set limit. If the system does not detect a low-load mode, the system enables all power modules to operate in CCM (step 1004), and loop back to step 1002. Conversely, the system determines if the low-load mode persists for a first predefined duration T1 (step 1006). If the low-load mode has not reached T1, the system continue to monitor the load demand (step 1002). If the low-load mode persists for or beyond T1, the system transitions selected power modules from CCM to DCM (step 1008). The system continues monitoring load demand and determine whether it is in low-load mode at step 1010. If the system is no longer in low-load mode (e.g., a load increase is detected) at step 1010, the system enables all power modules to operate in CCM (step 1004). If a low-load mode is detected at step 1010, the system then determines if the low-load mode persists for a second predefined duration T2 (step 1012). If the low-load mode has not reached T2, the system remain in DCM (step 1008) and keep monitoring load demand (step 1010). Conversely, if the low-load mode persists for at least T2 at step 1012, the system transitions selected power modules to sleep mode (step 1014). In some embodiments, one or more power modules operating in DCM are transitioned to sleep mode at step 1014 to further optimize energy efficiency. While in sleep mode, the system continuously monitors for a wake-up condition at step 1016. The wake-up condition may be met based on one or more conditions, such as detecting an increase in load demand, receiving a new system command indicating a higher power requirement, detecting a voltage drop at the output terminal beyond a predefined threshold, identifying other operational triggers that require additional power modules to be activated, or the expiration of a predefined time limit. If the wake-up condition is not met, the selected power modules remain in sleep mode (step 1014). In some embodiments, if a further decrease in load is detected while selected power modules are in sleep mode, the system may transition additional power modules to sleep mode at step 1014. Conversely, if the wake-up condition is met in step 1016, the system immediately reactivates the power modules from sleep mode and transitions them into DCM (step 1008). If no low-load mode is detected at step 1010, the system fully restores power by re-entering CCM (step 1004). However, if low-load mode is still detected at step 1010, the selected power modules remain in DCM and the system restarts counting the duration of low-load mode to determine whether further transitions to sleep mode (step 1014) are necessary. This approach ensures efficient power utilization, minimizing energy waste during periods of low demand while allowing a fast response to load variations.

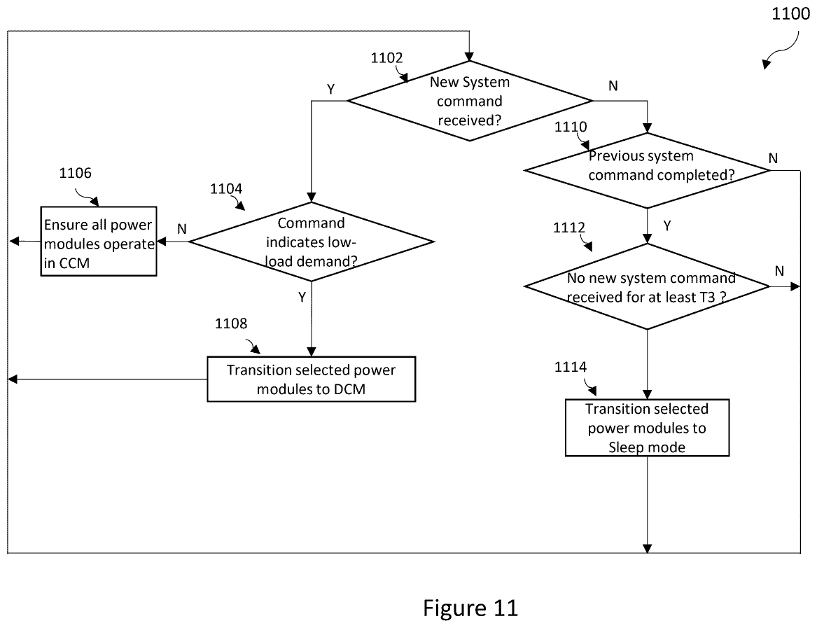

FIG. 11 is a flowchart of an example method 1100 for controlling a variable current load system in accordance with various embodiments of the present disclosure. The method 1100 provides example operations performed at a fuel cell system, particularly in forklift applications, where the fuel cell system 100 utilizes the system controller 116 in conjunction with the current load controller within the variable current load system 120, as described with respect to FIGS. 1-7.

The method 1100 begins by determining whether a new system command has been received (step 1102). The system commands provide information on load demand, determining whether it is high or low based on factors such as acceleration, lifting operations, or other functional requirements. If a new system command is received at step 1102, the system evaluates whether the system command indicates a low-load demand (step 1104). If the system command does not indicate a low-load demand, the system ensures all power modules operate in CCM (step 1106). If the system command indicates a low-load demand, the system transitions selected power modules from CCM to DCM (step 1108) to optimize efficiency under reduced load conditions. The system then loops back to step 1102 to continuously monitor new system commands. In some embodiments, when certain power modules are already operating in DCM, and the system detects a further decrease in load demand at step 1104, it may transition additional power modules from CCM to DCM to further optimize power efficiency. Conversely, if the system determines that a new system command received at step 1102 does not indicate a low-load demand at step 1104, it transitions the power modules operating in DCM back to CCM to accommodate the increased load demand (step 1106). If no new system command is received at step 1102, the system checks whether the operation corresponding to the previous system command has been completed (step 1110). If the previous system command is still active, the system remains in its current mode and continues monitoring for new system commands (returns to step 1102). If the previous system command has been completed, the system checks whether no new system command has been received for at least a predefined duration T3 (step 1112). If a new system command arrives before T3, the system returns to step 1102 and processes the new command accordingly. If no new system command is received for at least T3, the system transitions selected power modules to sleep mode (step 1114) to minimize energy consumption. The predefined duration T3 is carefully selected to ensure that the system remains in an idle state long enough to distinguish temporary pauses from extended inactivity, preventing premature transitions into sleep mode. While in sleep mode, the system continuously monitors for new system commands (step 1102). Upon receiving a new system command at step 1102, the system reactivates the power modules from sleep mode and adjusts their operation to either DCM or CCM, based on the reevaluation at step 1104.

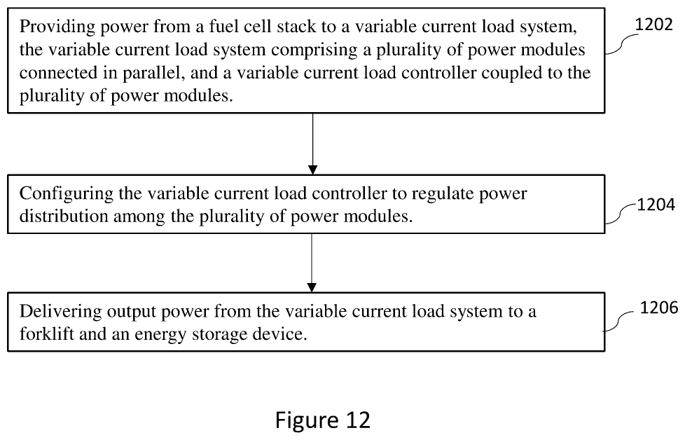

FIG. 12 illustrates a flow chart of a method for controlling a variable current load system in accordance with various embodiments of the present disclosure.

At step 1202, providing power from a fuel cell stack to a variable current load system, the variable current load system comprising a plurality of power modules connected in parallel, and a variable current load controller coupled to the plurality of power modules.

At step 1204, configuring the variable current load controller to regulate power distribution among the plurality of power modules.

At step 1206, delivering output power from the variable current load system to a forklift and an energy storage device.

The method further comprises configuring the variable current load controller to distribute a current load equally among the plurality of power modules, wherein each power module is configured as a buck-boost converter.

In some embodiments, each power module of the plurality of power modules is a buck-boost converter comprising a first switch and a second switch connected in series between an input of the buck-boost converter and ground; a third switch and a fourth switch connected in series between an output of the buck-boost converter and ground; an inductor connected between a common node of the first switch and the second switch, and a common node of the third switch and the fourth switch; a resistor and a capacitor connected in series between two terminals of the inductor; a current-sense amplifier configured to receive signals from two terminals of the capacitor and generate a current sense voltage; a slope compensation block configured to generate a slope compensation ramp signal, wherein the slope compensation ramp signal is combined with the current sense voltage to produce a compensated current sense signal; an error amplifier configured to receive a reference voltage at its non-inverting input terminal and a feedback voltage at its inverting input terminal, wherein the feedback voltage is proportional to the output voltage of the system; a comparator configured to receive an output signal of the error amplifier at its non-inverting input and the compensated current sense signal at its inverting input; a control logic unit configured to receive an output signal of the comparator and generate pulse-width modulation (PWM) drive signals to control switching of the first, second, third, and fourth switches in the power module; and a feedback resistor, wherein the feedback resistor is configured to be adjusted via a Serial Peripheral Interface (SPI) varistor by the variable current load controller to regulate an output current of each power module to maintain balanced current distribution among the plurality of power modules.

The method further comprises configuring the variable current load controller to receive a current load request via a controller area network (CAN) interface; allocating the current load request among active power modules of the plurality of power modules; transmitting operational commands to the plurality of power modules via a Serial Peripheral Interface (SPI) while ensuring that each power module of the plurality of power modules operates within predefined temperature limits; and collecting and relaying system performance data over the CAN interface for real-time monitoring and control.

The method further comprises monitoring a load demand based on one or more predefined conditions; enabling one or more power modules operating in Continuous Conduction Mode (CCM) to enter Discontinuous Conduction Mode (DCM) when the load demand remains low for a first predefined duration; distributing the load demand among all active power modules of the plurality of power modules, wherein power modules in CCM are configured to contribute equal current, while power modules in DCM are configured to contribute a reduced current; and monitoring load changes and transitioning the power modules operating in DCM back to CCM when an increase in load demand is detected.

The method further comprises transitioning one or more power modules operating in DCM to a sleep mode if the load demand remains low for a second predefined duration; and transitioning power modules power modules operating in sleep mode to DCM when a wake-up condition is met, and transitioning additional power modules operating in DCM to sleep mode when a further decrease in load demand is detected.

The method further comprises enabling one or more power modules operating in CCM to enter DCM when a system command received by the current load controller indicates a low load demand, wherein the low load demand is determined based on a predefined condition; distributing the current request among all active power modules, wherein power modules in CCM are configured to contribute equal current, while power modules in DCM are configured to contribute a reduced current; and transitioning the power modules operating in DCM back to CCM when a subsequent system command does not indicate a low load demand.

The method further comprises transitioning one or more power modules to a sleep mode when the forklift has completed execution of a previous system command, and no new system command has been received by the variable current load controller for a predefined duration; transitioning the power modules operating in sleep mode to DCM upon receiving a new system command that indicates a low load demand, as determined based on the predefined condition; and transitioning the power modules operating in sleep mode to CCM upon receiving a new system command that does not indicate a low load demand, as determined based on the predefined condition.

Although embodiments of the present disclosure and its advantages have been described in detail, it should be understood that various changes, substitutions and alterations can be made herein without departing from the spirit and scope of the disclosure as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A system comprising:
a plurality of power modules connected in parallel, with input terminals of the plurality of power modules configured to be coupled to an output of a fuel cell stack and output terminals of the plurality of power modules configured to supply power to a forklift, wherein the plurality of power modules is configured to provide electrical isolation between the fuel cell stack and the forklift; and
a variable current load controller coupled to the plurality of power modules, wherein the variable current load controller is configured to regulate power distribution among the plurality of power modules.

2. The system of claim 1, further comprising an energy storage contactor and a vehicle contactor, wherein:
the output terminals of the plurality of power modules are further configured to be coupled to an energy storage device through the energy storage contactor, and wherein the energy storage device comprises a plurality of battery cells;
the output terminals of the plurality of power modules are further configured to be coupled to the forklift through the vehicle contactor; and
the energy storage contactor and the vehicle contactor are configured to regulate the transfer of stored energy from the energy storage device to the forklift.

3. The system of claim 2, wherein each power module of the plurality of power modules is configured as a buck-boost converter comprising:
a first switch and a second switch connected in series between an input of the power module and ground;
a third switch and a fourth switch connected in series between an output of the power module and ground; and
an inductor connected between a common node of the first switch and the second switch, and a common node of the third switch and the fourth switch.

4. The system of claim 3, wherein each power module of the plurality of power modules further comprises:
a resistor and a capacitor connected in series between two terminals of the inductor;
a current-sense amplifier configured to receive signals from two terminals of the capacitor and generate a current sense voltage;
a slope compensation block configured to generate a slope compensation ramp signal, wherein the slope compensation ramp signal is combined with the current sense voltage to produce a compensated current sense signal;
an error amplifier configured to receive a reference voltage at its non-inverting input terminal and a feedback voltage at its inverting input terminal, wherein the feedback voltage is proportional to the output voltage of the system;
a comparator configured to receive an output signal of the error amplifier at its non-inverting input and the compensated current sense signal at its inverting input;
a control logic unit configured to receive an output signal of the comparator and generate pulse-width modulation (PWM) drive signals to control switching of the first, second, third, and fourth switches in the power module; and
a feedback resistor, wherein the feedback resistor is configured to be adjusted via a Serial Peripheral Interface (SPI) varistor by the variable current load controller to regulate an output current of each power module to maintain balanced current distribution among the plurality of power modules.

5. The system of claim 1, wherein the variable current load controller is further configured to regulate the plurality of power modules to ensure equal current distribution, wherein each power module of the plurality of power modules is configured as a buck-boost converter.

6. The system of claim 1, wherein:
the variable current load controller is further configured to receive a current load request via a controller area network (CAN) interface, allocate the current load request among active power modules of the plurality of power modules, transmit operational commands to the plurality of power modules via a Serial Peripheral Interface (SPI) while ensuring that each power module of the plurality of power modules operates within predefined temperature limits, and collect and relay system performance data over the CAN interface for system monitoring and control.

7. The system of claim 6, wherein:
one or more power modules from the plurality of power modules are configured to transition from Continuous Conduction Mode (CCM) to Discontinuous Conduction Mode (DCM) when a load demand remains low for a first predefined duration, and wherein the load demand is determined based on one or more predefined conditions, and power modules in CCM are configured to contribute equal current, while power modules in DCM are configured to contribute a reduced current;
power modules operating in DCM are configured to transition to CCM when an increase in load demand is detected;
one or more power modules operating in DCM are configured to transition to a sleep mode if load demand remains low for a second predefined duration; and
power modules operating in the sleep mode are configured to transition to DCM when a wake-up condition is met.

8. The system of claim 6, wherein:
one or more power modules from the plurality of power modules are configured to transition from CCM to DCM when a system command received by the current load controller indicates a low load demand, wherein power modules in CCM are configured to contribute equal current, while power modules in DCM are configured to contribute a reduced current;
power modules operating in DCM are configured to transition to CCM when a subsequent system command received by the current load controller does not indicate a low load demand;
one or more power modules are configured to transition to a sleep mode when the forklift has completed execution of a previous system command, and no new system command has been received by the variable current load controller for a predefined duration;
power modules operating in the sleep mode are configured to transition to DCM when a new system command received by the variable current load controller indicates a low load demand; and
power modules operating in the sleep mode are configured to transition to CCM when a new system command received by the variable current load controller does not indicate a low load demand.

9. The system of claim 2, further comprising:
a fuel storage tank, wherein the fuel cell stack is configured to receive fuel from the fuel storage tank and generate electrical power;
a pressure regulator configured to control a fuel pressure within the fuel storage tank;
a radiator fan configured to dissipate heat generated during operation of the fuel cell stack;
a coolant pump configured to circulate coolant throughout the system;
one or more sensors configured to measure parameters of the system; and
a system controller configured to monitor and control operation of the system, wherein the variable current load controller is configured to receive a current load request from the system controller via a controller area network (CAN) interface, and further configured to collect and relay system performance data over the CAN interface to the system controller for system monitoring and controlling.

10. The system of claim 9, wherein:
the energy storage contactor and the vehicle contactor are mounted on an exterior surface of the system and extend above the exterior surface, and wherein the energy storage contactor and the vehicle contactor are controlled by the system controller.

11. A variable current load system comprising:
a plurality of power modules on a board in a package, wherein:
output terminals of the plurality of power modules are aligned with an output terminal of the package, and wherein the output terminal of the package is configured to supply power to a forklift;
input terminals of the plurality of power modules are aligned with an input terminal of the package, and wherein the input terminal of the package is configured to be connected to an output terminal of a fuel cell stack; and
the plurality of power modules is configured to emulate a battery providing power to the forklift; and
a variable current load controller on the board and parallel to the plurality of power modules, wherein the variable current load controller is configured to regulate power distribution among the plurality of power modules.

12. The variable current load system of claim 11, wherein:
a power module of the plurality of power modules is placed on a printed circuit board, and wherein each power module of the plurality of power modules comprises a plurality of input capacitors, a first power switch, a second power switch, a third power switch, a fourth power switch, a magnetic device, a plurality of output capacitors, and a controller, and wherein:
the plurality of input capacitors is placed between a ground node and an input terminal of the power module;
the plurality of output capacitors is placed between a ground node and an output terminal of the power module;
the magnetic device is centrally positioned on the printed circuit board;
the first power switch is placed between the plurality of input capacitors and the magnetic device, with a first side of the first power switch aligned with a first side of the magnetic device and a second side of the first power switch aligned with a second side of the magnetic device;
the second power switch is placed adjacent to the magnetic device and the controller, with a first side of the second power switch aligned with the second side of the magnetic device;
the third power switch is placed adjacent to the magnetic device and the controller, with a first side of the third power switch aligned with the second side of the magnetic device;
the controller is placed between the second power switch and the third power switch, with a first side of the controller aligned with the second side of the magnetic device; and
the fourth power switch is placed between the plurality of output capacitors and the magnetic device, with a first side of the fourth power switch aligned with a third side of the magnetic device and a second side of the fourth power switch aligned with the second side of the magnetic device.

13. A method comprising:
providing power from a fuel cell stack to a variable current load system, the variable current load system comprising a plurality of power modules connected in parallel, and a variable current load controller coupled to the plurality of power modules;
configuring the variable current load controller to regulate power distribution among the plurality of power modules; and
delivering output power from the variable current load system to a forklift and an energy storage device.

14. The method of claim 13, further comprising:
configuring the variable current load controller to distribute a current load equally among the plurality of power modules, wherein each power module is configured as a buck-boost converter.

15. The method of claim 13, wherein each power module of the plurality of power modules is a buck-boost converter comprising:
a first switch and a second switch connected in series between an input of the buck-boost converter and ground;
a third switch and a fourth switch connected in series between an output of the buck-boost converter and ground;
an inductor connected between a common node of the first switch and the second switch, and a common node of the third switch and the fourth switch;
a resistor and a capacitor connected in series between two terminals of the inductor;
a current-sense amplifier configured to receive signals from two terminals of the capacitor and generate a current sense voltage;
a slope compensation block configured to generate a slope compensation ramp signal, wherein the slope compensation ramp signal is combined with the current sense voltage to produce a compensated current sense signal;
an error amplifier configured to receive a reference voltage at its non-inverting input terminal and a feedback voltage at its inverting input terminal, wherein the feedback voltage is proportional to the output voltage of the system;
a comparator configured to receive an output signal of the error amplifier at its non-inverting input and the compensated current sense signal at its inverting input;
a control logic unit configured to receive an output signal of the comparator and generate pulse-width modulation (PWM) drive signals to control switching of the first, second, third, and fourth switches in the power module; and
a feedback resistor, wherein the feedback resistor is configured to be adjusted via a Serial Peripheral Interface (SPI) varistor by the variable current load controller to regulate an output current of each power module to maintain balanced current distribution among the plurality of power modules.

16. The method of claim 13, further comprising:
configuring the variable current load controller to receive a current load request via a controller area network (CAN) interface;
allocating the current load request among active power modules of the plurality of power modules;
transmitting operational commands to the plurality of power modules via a Serial Peripheral Interface (SPI) while ensuring that each power module of the plurality of power modules operates within predefined temperature limits; and
collecting and relaying system performance data over the CAN interface for real-time monitoring and control.

17. The method of claim 16, further comprising:
monitoring a load demand based on one or more predefined conditions;
enabling one or more power modules operating in Continuous Conduction Mode (CCM) to enter Discontinuous Conduction Mode (DCM) when the load demand remains low for a first predefined duration;
distributing the load demand among all active power modules of the plurality of power modules, wherein power modules in CCM are configured to contribute equal current, while power modules in DCM are configured to contribute a reduced current; and
monitoring load changes and transitioning the power modules operating in DCM back to CCM when an increase in load demand is detected.

18. The method of claim 17, further comprising:
transitioning one or more power modules operating in DCM to a sleep mode if the load demand remains low for a second predefined duration; and
transitioning power modules power modules operating in sleep mode to DCM when a wake-up condition is met, and transitioning additional power modules operating in DCM to sleep mode when a further decrease in load demand is detected.

19. The method of claim 16, further comprising:
enabling one or more power modules operating in CCM to enter DCM when a system command received by the current load controller indicates a low load demand, wherein the low load demand is determined based on a predefined condition;
distributing the current request among all active power modules, wherein power modules in CCM are configured to contribute equal current, while power modules in DCM are configured to contribute a reduced current; and
transitioning the power modules operating in DCM back to CCM when a subsequent system command does not indicate a low load demand.

20. The method of claim 19, further comprising:
transitioning one or more power modules to a sleep mode when the forklift has completed execution of a previous system command, and no new system command has been received by the variable current load controller for a predefined duration;
transitioning the power modules operating in sleep mode to DCM upon receiving a new system command that indicates a low load demand, as determined based on the predefined condition; and
transitioning the power modules operating in sleep mode to CCM upon receiving a new system command that does not indicate a low load demand, as determined based on the predefined condition.
